(19) United States
(12) Patent Application Publication
(10) Pub. No.: US 2026/0360396 A1
(43) Pub. Date: Nov. 12, 2026

(54) Voltage Transition Management Circuitry and Methods

(71) Applicant: Arm Limited, Cambridge (GB)

(72) Inventors: Utkarsh Singh, Greater Noida (IN); Parmanand Singh, Ghaziabad (IN); Piyush Jain, Greater Noida (IN); Andy Wangkun Chen, Austin, TX (US); Ashish Bhardwaj, Noida (IN); Rahul Kumar Jaisawal, Greater Noida (IN)

(21) Appl. No.: 19/202,939

(22) Filed: May 8, 2025

(51) Int. Cl. G11C 5/14

(52) U.S. Cl. CPC G11C 5/144

(57) ABSTRACT

A circuit for managing voltage transitions comprising: a memory array comprising a plurality of memory bitcells; a plurality of input-output (I/O) regions comprising a plurality of power multiplexers (PMUXes), each PMUX comprising a first header and a second header configured to selectively couple a first voltage supply or a second voltage supply to respective memory bitcells within the memory array; control circuitry coupled to a global signal line and configured to generate a global control signal, wherein the global signal line is configured to propagate the global control signal to each of the plurality of PMUXes; and adaptive circuitry coupled to the global signal line, wherein the adaptive circuitry is configured to generate complementary local control signals.

### I. FIELD

The present disclosure is generally related to systems, methods, and circuit devices for voltage transition management.

### II. DESCRIPTION OF RELATED ART

In integrated memory circuits, especially static random-access memory (SRAM), maintaining continuous and stable power supply to the memory cells is critical to preventing data corruption. Such memory circuits often incorporate power multiplexers to dynamically switch between different voltage external supplies (e.g., VDDPE and VDDCE) based on operational requirements such as read, write, and power-down modes. However, the process of switching power supplies within SRAM introduces significant challenges. Notably, two critical issues arise: (1) maintaining overlap during switching between the two power supplies to prevent a floating output, and (2) minimizing the spatial voltage skew caused by propagation delays in control signals across the memory array.

Specifically, when transitioning between two power supplies, it is important to ensure a controlled overlap, where one power supply is enabled slightly before the other is disabled, thereby preventing any interruption of power (e.g., a “floating” state). Excessive overlap, however, can create large crowbar currents, leading to unnecessary power dissipation and reliability concerns. Moreover, the control signals responsible for switching the power multiplexers experience propagation delays due to distributed routing within the SRAM. Such delays create spatial skews, resulting in non-uniform voltage conditions across memory instances, potentially compromising functional margins and memory performance. Existing solutions, such as using pulse shaper circuits or oversized drivers, have limitations and often fail to effectively manage the overlap and spatial skew in large SRAM instances. Thus, there remains a pressing need for improved schemes and techniques to reliably manage power supply transitions in integrated SRA M power multiplexers, addressing specifically, both overlap race conditions and spatial voltage skews without incurring additional performance penalties.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a diagram of an example circuit in accordance with various implementations described herein.

FIG. 2 is a diagram of an example circuit in accordance with various implementations described herein.

FIGS. 3A-3C are each diagrams of example circuits in accordance with various implementations described herein.

FIG. 4 is a diagram of an example circuit in accordance with various implementations described herein.

FIG. 5 is a diagram of an example circuit in accordance with various implementations described herein.

FIG. 6 is a diagram of an example circuit in accordance with various implementations described herein.

FIG. 7 is a diagram of an example circuit in accordance with various implementations described herein.

FIG. 8 is an operational method in accordance with various implementations described herein.

FIG. 9 is an operational method in accordance with various implementations described herein.

FIG. 10 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

In one implementation, the present disclosure describes a circuit for managing voltage transitions. The circuit includes: 1) a memory array including a plurality of memory bitcells; 2) a plurality of input-output (I/O) regions including a plurality of power multiplexers (PMUXes), each PMUX having a first header and a second header configured to selectively couple a first voltage supply or a second voltage supply to respective memory bitcells within the memory array; 3) control circuitry coupled to a global signal line and configured to generate a global control signal, where the global signal line is configured to propagate the global control signal to each of the plurality of PMUXes; and 4) adaptive circuitry coupled to the global signal line, where the adaptive circuitry is configured to generate complementary local control signals.

In another implementation, the present disclosure describes a circuit for managing voltage transitions. The circuit includes: 1) a memory array comprising a plurality of memory bitcells; 2) a plurality of input-output (I/O) regions comprising power multiplexers (PMUXes), each PMUX comprising a first header and a second header configured to selectively couple a first voltage supply or a second voltage supply to respective memory bitcells within the memory array; and 3) a plurality of localized level shifter circuits, each localized level shifter circuit positioned proximate to a respective PMUX within each I/O region and configured to convert a globally propagated control signal into complementary local control signals. Also, each localized level shifter circuit is configured to provide timing offsets between the complementary local control signals.

In another implementation, the present disclosure describes a method for managing voltage transitions. The method includes: 1) generating a global control signal from a control circuit; 2) propagating the global control signal across a global signal line to power muxes distributed in I/O regions of a memory array; and 3) generating complementary local control signals based on tracked loading along the global signal line or circuit conditions/configurations during power down transitions.

In another implementation, the present disclosure describes a method of managing voltage transitions. The method includes: 1) generating a global control signal from a control circuit; 2) propagating the global control signal across a global signal line to power multiplexers (PMUXes) distributed in input-output (I/O) regions of a memory array; and 3) tracking capacitance (C) or resistance-capacitance (RC) loading along the global signal line using adaptive circuitry.

Inventive aspects provide innovative methods and circuits for managing voltage transitions in integrated power multiplexers (PMUXes) within static random-access memory (SRAM) arrays, effectively addressing critical technical challenges such as overlap race conditions, crowbar currents, and spatial voltage skew.

Specific inventive approaches include: 1) Adaptive Cross-Coupled Feedback Circuitry (SR Latch-Based Delay Tracking; 2) Localized Timing Control via Level Shifter Reuse; and 3) Global-to-Local Signal Tracking for Spatial Voltage Skew Minimization.

For instance, in a first approach, the invention provides adaptive feedback circuitry utilizing a modified cross-coupled Set-Reset (SR) latch structure configured to dynamically manage timing offsets between complementary global control signals (e.g., SEL_VL and nSEL_VL). This adaptive circuitry dynamically tracks global loading conditions, including capacitance (C) loading or resistance-capacitance (RC) loading, on global signal lines to generate adaptive timing skews responsive to memory array size, circuit routing conditions, and operational requirements. Programmable delay elements within the adaptive feedback circuitry further enable precise adjustment and fine-tuning of timing relationships between complementary local control signals (SEL_PG, nSEL_PG). During voltage transitions, this adaptive feedback configuration ensures that one voltage supply header (e.g., a VDDPE header) is reliably enabled before the complementary voltage supply header (e.g., a VDDCE header) is disabled, thereby maintaining continuous power delivery without incurring excessive overlap or crowbar currents. Advantageously, the adaptive feedback circuitry explicitly prevents simultaneous activation of complementary headers during transitions into and out of power-down modes, significantly reducing transient currents and enhancing operational reliability.

According to a second approach, the invention leverages existing localized level shifter circuits positioned within individual input-output (I/O) regions to convert global timing race conditions into localized timing control. In particular, localized level shifter circuits originally powered from a primary voltage domain (e.g., VDDPE) are instead powered from an always-on stable intermediate voltage domain (e.g., VNWPC). Utilizing this stable voltage domain, these localized level shifters locally generate complementary intermediate signals (e.g., iSEL_VL, inSEL_VL) derived from globally propagated control signals. Combinational logic positioned locally within each I/O region combines these intermediate signals with a globally propagated power-down signal (PDW), thereby generating complementary local control signals (e.g., SEL_PG, nSEL_PG) utilized directly for precise control of PMUX headers. Advantageously, this inventive reuse of existing level-shifter circuitry effectively localizes timing management, significantly reducing spatial voltage skew across the memory array, simplifying central control circuit complexity, and minimizing crowbar currents during voltage transitions.

In certain aspects, a third approach includes global-to-local signal tracking for effectively mitigating spatial voltage skew across distributed memory arrays. Specifically, global control signals (e.g., SEL_VL) propagate across multiple I/O regions via optimized low-resistance conductor tracks. Local driver circuits positioned periodically along these global signal lines selectively activate, reinforcing signal transitions. Initially, localized drivers positioned nearer to the central control region attempt early transitions of the global signals. However, due to inherent propagation delays, localized drivers positioned further from the central control region initially counteract these transitions, resulting in uniform discharge across the global signal line. Consequently, PMUX activation occurs substantially simultaneously across all I/O regions, significantly reducing spatial voltage skew. Selective periodic positioning and activation of localized driver circuits further reduce transient peak currents and power consumption, providing a robust, scalable solution without additional overhead or complexity.

Certain definitions are provided herein for clarity and reference. As used herein, a memory macro refers to an integrated memory circuit block including multiple functional sections. These sections typically include a bitcell array, wordline driver circuitry, column multiplexing circuitry, local input-output (I/O) circuitry, central timing or clocking circuitry, control logic, and dedicated internal power distribution meshes (e.g., VDDC, VDDCX). Memory macros can be implemented in various layout configurations, such as butterfly architectures characterized by centrally located wordline drivers and peripheral I/O circuitry. These layouts provide balanced loading, optimized power distribution, and improved memory performance. A memory macro therefore represents a self-contained memory unit suitable for integration within larger semiconductor devices, system-on-chip (SoC) architectures, processors, or other integrated circuit designs.

A memory array refers to a structured arrangement of memory bitcells organized in rows and columns within an integrated memory circuit such as a memory macro. A bitcell array specifically denotes a structured configuration of memory bitcells within a memory macro, arranged to store data bits. Example bitcell arrays include static random-access memory (SRAM), dual-port memory arrays, multi-port memory arrays, and dedicated read/write-port memory arrays such as eight-transistor (8T) bitcell configurations. Memory bitcells are individual storage elements within the memory array, each capable of storing one bit of information (e.g., logic “0” or “1”).

Input-output (I/O) regions refer to regions adjacent to or near a memory array comprising circuitry that manages input/output operations, including power multiplexers (PMUXes), local drivers, localized level shifters, and signal routing structures. A power multiplexer (PMUX) is a circuit configured to selectively couple memory bitcells to one of two or more available voltage supplies, enabling dynamic selection of voltage levels supplied to memory bitcells. A PMUX typically includes transistor devices (such as PM OS transistors) arranged to selectively switch between external voltage domains based on control signals, providing dynamic switching capability for voltage supplies delivered to internal power meshes or bitcells.

PMUX headers (or power headers) refer specifically to transistor devices, typically pairs of PM OS transistors within a PMUX, configured to selectively couple an internal power mesh to one of two or more external voltage domains based on control signals. Each transistor within the pair is coupled to a respective external voltage domain. Headers in this context refer generally to transistor devices configured within a PMUX to couple or decouple voltage supplies to or from memory bitcells based on complementary local control signals.

A global signal line denotes a conductive path routed across multiple regions of an integrated memory circuit to propagate global control signals from central control circuitry to distributed circuits. Global control signals are centrally generated signals propagated along global signal lines used to control distributed circuit elements such as PMUXes, local drivers, and localized level shifters. Examples of global control signals include SEL_VL and nSEL_VL.

Local control signals are signals derived locally within individual I/O regions from global control signals. These signals directly control local PMUX headers. For example, complementary local control signals such as SEL_PG and nSEL_PG are locally derived from global signals (e.g., SEL_VL and nSEL_VL) using localized level shifter circuitry and combinational logic. Localized level shifter circuits convert globally propagated signals into complementary local control signals, shifting voltage levels suitable for local circuitry within each I/O region. A voltage domain represents a region or portion of an integrated circuit powered by a specific voltage supply level defining the operating voltage for associated circuit elements.

Tracking circuitry dynamically monitors electrical characteristics such as capacitance (C) or resistance-capacitance (RC) loading along global signal lines and adaptively generates local control signals having timing offsets based on measured loading. Resistance-capacitance (RC) loading refers to the electrical loading characteristics defined by inherent resistance and associated capacitances arising from distributed device loads, wiring, and transistor gates, impacting signal propagation delays. Adaptive timing skew refers to timing offsets between complementary signals dynamically adjusted based on real-time tracking of electrical characteristics (e.g., C or RC loading) to ensure desired timing overlap, reduce voltage skew, or prevent crowbar currents.

Feedback circuitry is circuit elements configured to detect output conditions or signal characteristics (such as RC loading or timing states) and dynamically generate corrective responses in a feedback loop to control timing of signal generation. Cross-coupled feedback paths are specific configurations of feedback circuitry employing mutually interconnected circuit paths typically forming latch structures, such as Set-Reset (SR) latches, ensuring stable adaptive control of signal timing and voltage transitions. Programmable delay elements within feedback circuitry selectively introduce variable delays into electrical signals, enabling adaptive timing adjustments based on measured conditions or operational requirements.

Local drivers are circuit elements distributed periodically along global signal lines and selectively activated to reinforce signal propagation, minimizing RC delay, reducing spatial voltage skew, and controlling peak power or current consumption during transitions. Mixing circuitry includes circuit elements configured to logically combine signals (e.g., such as global control signals, intermediate local signals, and power-down signals) to generate desired local control signals with specified timing relationships. A power-down control signal (PDW) is a centrally generated signal indicating power-down or power-up conditions, utilized locally within I/O regions to disable or enable PMUX headers during power transitions, ensuring controlled overlap between voltage supplies. Simultaneous activation refers to a condition where distributed PMUXes across multiple I/O regions activate substantially concurrently, minimizing spatial voltage skew. Controlled timing overlap indicates a precisely managed temporal overlap between enabling one PMUX header and disabling another to ensure continuous power delivery without excessive crowbar currents or undesirable power interruptions (dead-zones).

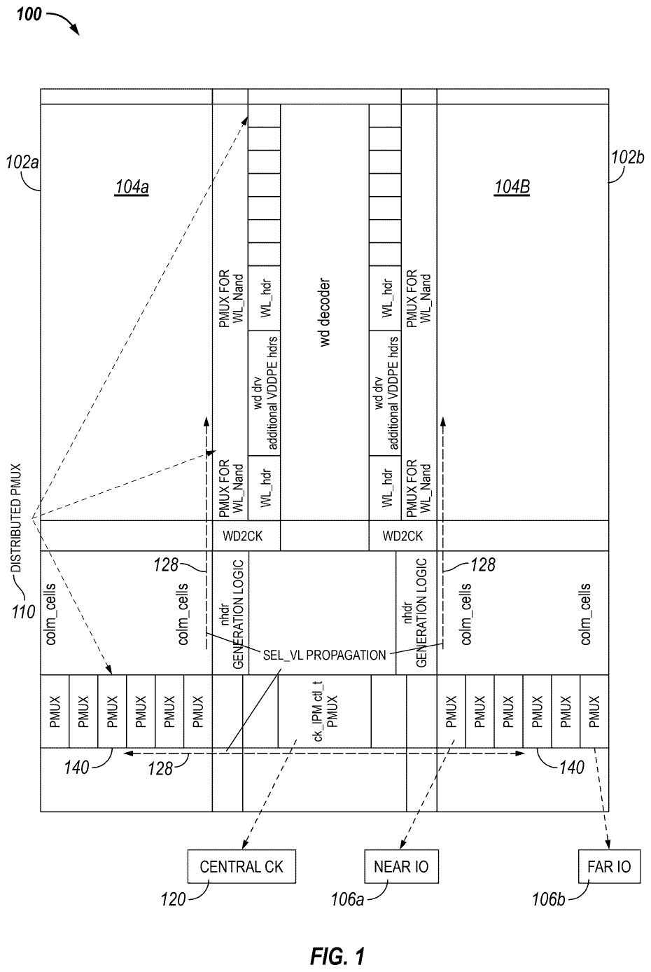

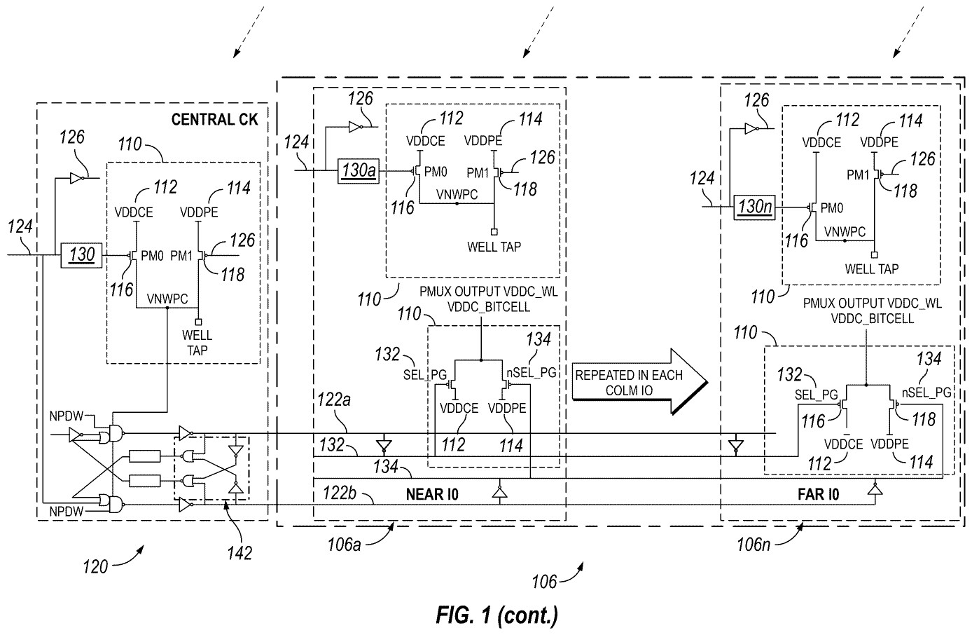

Referring to FIG. 1, a circuit 100 (e.g., integrated memory circuit, an SRAM memory macro) for managing voltage transitions is shown according to example implementations. In certain aspects, FIG. 1 depicts an integrated memory circuit 100 configured to minimize spatial voltage skew associated with resistance-capacitance (RC) delays of globally propagated signals controlling power multiplexers (PMUXes) within a memory array. As illustrated, the circuit 100 includes a memory array 102 (e.g., 102a, 102b, etc.) including a plurality of memory bitcells 104 (e.g., 104a, 104b, etc.) arranged within core array regions. The memory array 102 is arranged adjacent to a plurality of input-output (I/O) regions 106a, 106b, . . . , 106n, each including PMUXes 110 configured to selectively couple respective memory bitcells 104 within memory array 102 to either a first voltage supply, for example, VDDCE 112, or a second voltage supply, for example, VDDPE 114. As further depicted, each PMUX 110 includes a first header transistor 116 and a second header transistor 118, selectively coupling respective voltage supplies (e.g., VDDCE 112 or VDDPE 114) to memory bitcells 104. As may be appreciated, the layout illustrates distributed placement of PMUXes 110 across the I/O regions 106a-106n, providing localized coupling between memory bitcells 104 and voltage supplies 112, 114.

In certain implementations, the circuit 100 further includes a central control circuit (Central CK) 120) configured to generate complementary global control signals, specifically SEL_VL 124 and nSEL_VL 126. These complementary global signals SEL_VL 124 and nSEL_VL 126 are propagated along global signal lines 128 (e.g., SEL_VL propagation) distributed across the plurality of I/O regions 106a-106n. Each global signal line 128 includes a low-resistance conductive track configured to reduce capacitance (C) or resistance-capacitance (RC) delays and minimize voltage skew as signals propagate from a near IO region (e.g., 106a) to a far IO region (e.g., 106n) of the circuit 100. Nevertheless, despite this low-resistance routing, residual C or RC delays remain significant, particularly between the near IO region 106a and the far IO region 106n. As further illustrated, the complementary global control signals generated by central control circuit 120 include signals BSEL_PG 122a and BNSEL_PG 122b, which propagate across global signal lines 128.

In various cases, to further mitigate spatial voltage skew, the circuit 100 includes localized level shifter circuits 130 (e.g., 130a . . . 130n) positioned in proximity to or within each PMUX 110 of the respective I/O regions 106a-106n. Each localized level shifter circuit 130 converts the globally propagated signals, for example, SEL_VL 124 and nSEL_VL 126, into complementary local control signals SEL_PG 132 and nSEL_PG 134. The localized level shifter circuits 130 (e.g., 130a . . . 130n) inherently provide intrinsic timing offsets established by their internal transistor-level configurations. Such intrinsic timing offsets precisely control timing overlaps between enabling of one header transistor 116 and disabling of the complementary header transistor 118 within each PMUX 110. Accordingly, the localized level shifter circuits 130 prevent simultaneous activation (i.e., allow for non-simultaneous activation) of complementary headers 116, 118, thereby reducing crowbar currents and preventing floating nodes during power transitions.

Additionally, the circuit 100 includes programmable local driver circuits 140 selectively coupled at intermittent I/O regions (e.g., every fourth region along the global signal lines 128). These programmable local driver circuits 140 actively reinforce propagation of signals SEL_PG 132 and nSEL_PG 134 across the global signal lines 128. By selectively activating programmable local drivers 140, resistance-capacitance (RC) loading or capacitance (C) loading along the global signal lines 128 is dynamically reduced, moderating sharp signal transitions and effectively minimizing spatial voltage skew. Thus, these selectively activated local drivers 140 enhance uniform activation timing of PMUX headers 116, 118 throughout the circuit 100.

Moreover, the circuit 100 includes adaptive circuitry (described in greater detail in later paragraphs) coupled to the global signal line 128, specifically including adaptive tracking and/or feedback circuitry 142 (see FIG. 1 cont.). The adaptive circuitry 142 includes cross-coupled feedback paths, illustrated as an SR latch configuration, configured to dynamically track resistance-capacitance (RC) loading or capacitance (C) loading on the global signal line 128. Based on this dynamically tracked loading, the adaptive circuitry 142 generates complementary local control signals (e.g., SEL_PG 132 and nSEL_PG 134) having dynamically adjusted timing offsets. These dynamically adjusted timing offsets ensure substantially simultaneous activation of PMUXes 110 across the plurality of I/O regions 106a-106n, significantly reducing spatial voltage skew.

Further, as illustrated, signals controlling PMUX PM OS gates, specifically SEL_PG 132 and nSEL_PG 134, are routed globally on low-resistance global signal lines 128 and are driven by programmable local driver circuits 140 selectively positioned at intervals within column I/O regions 106a-106n. During transitions, local driver circuits 140 positioned near the central control circuit 120 initially attempt to transition the SEL_PG signal 132. However, local driver circuits 140 located in far I/O regions (e.g., regions farther from the central control circuit 120) temporarily counteract this early signal transition due to inherent propagation delays along global signal line 128. As a result, SEL_PG signal 132 achieves a complete transition only after activation of local driver circuits 140 in both near and far column I/O regions, thereby ensuring substantially simultaneous activation of PMUXes 110 across all column I/O regions. Due to the infrequent toggling of SEL_PG 132 and nSEL_PG 134 signals, small short-circuit currents momentarily occurring between activated local driver circuits 140 do not significantly impact overall circuit performance or reliability. In certain aspects, logic circuits and inverters coupled between rails for BSEL_PG 122a-SEL_PG 132, and for BNSEL_PG 122b-nSEL_PG 134, as well as associated logic within each PMUX 110, operate at the voltage domain provided by the PMUX output (e.g., the PMUX output voltage domain), thereby ensuring consistent signal levels and reliable operation during transitions.

Additionally, in certain aspects (as described in greater detail in later paragraphs), adaptive feedback circuitry 142 independently generates complementary local control signals based on initial circuit conditions (e.g., the circuit configuration) particularly during transitions to and from a power-down mode (e.g., signals transitioning to and from power-down states). Specifically, in power-down mode, the power-down signals have fixed logical states (e.g., PDW=1 and NPDW=0), and under these conditions, cross-coupled feedback circuitry ensures that the feedback input to the OR gates of the set-reset (SR) latch remains logically “0.” Thus, upon transitioning out of the power-down mode (e.g., PDW transitioning to 0 and NPDW to 1), the OR gates within the SR latch feedback circuit portion generate complementary signals based on the SEL_VL input state at the initiation of the transition. Consequently, this initialization reliably ensures complementary signal generation independent of RC or C loading, thereby preventing simultaneous activation (i.e., allow for non-simultaneous activation) of headers 116 and 118 within each PMUX 110 and effectively eliminating crowbar currents. Therefore, adaptive feedback circuitry 142 advantageously avoids crowbar currents that might otherwise arise if both voltage supplies 112, 114 were simultaneously coupled to memory bitcells 104. In this manner, the integrated memory circuit 100 of FIG. 1 employs dynamically adaptive generation of complementary local control signals based independently on both tracked RC/C loading and initial circuit conditions. These adaptive local control signals ensure uniform activation of PMUX headers 116, 118 across the memory array 102 and precise control of timing overlaps, thereby effectively minimizing spatial voltage skew, preventing crowbar currents, and significantly enhancing power delivery reliability and robustness within memory circuit 100.

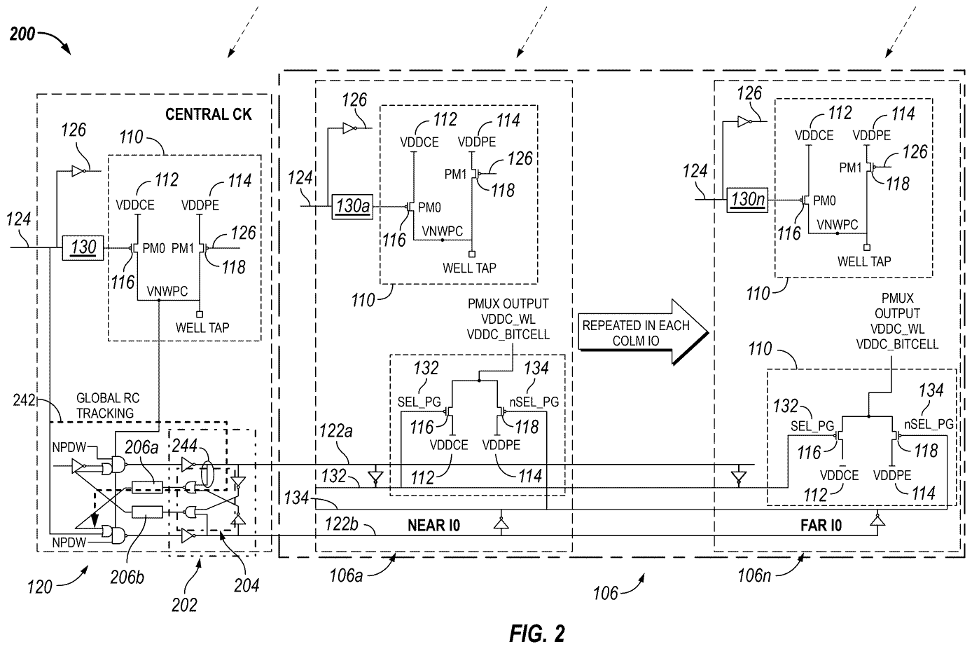

Referring to FIG. 2, a circuit 200 implementing example adaptive feedback-based delay tracking is shown according to example implementations. In certain aspects, the circuitry 200 (e.g., adaptive feedback-based delay tracking circuitry; adaptive circuitry; adaptive feedback circuitry; adaptive tracking circuitry) is configured to ensure robust timing overlap margins for controlling voltage transitions in a memory array 102 comprising multiple column input-output (I/O) regions 106a-106n. As previously described with reference to FIG. 1, the central control circuit (Central CK) 120 generates complementary global control signals SEL_VL 124 and nSEL_VL 126 that propagate via low-resistance global signal lines 128 distributed across the plurality of I/O regions 106a-106n.

In some implementations, the circuitry 200 includes an additional set-reset latch-based (SR latch) feedback circuit 202 that is specially configured to dynamically track resistance-capacitance (RC) loading on global signal lines 128. Notably, this SR latch feedback circuit 202 includes complementary cross-coupled logic gates 204 forming an additional cross-coupled latch structure, configured explicitly to manage voltage transition overlap conditions. The adaptive tracking circuitry 200 further incorporates programmable delay elements (PROG delays) 206a, 206b selectively integrated into signal paths within the SR latch feedback circuit 202. These programmable delay elements 206a, 206b are adjustable, allowing dynamic tuning of timing offsets between complementary local control signals SEL_PG 132 and nSEL_PG 134 based explicitly on RC loading measured via feedback paths, thus adaptively generating precise timing skews responsive to the number of columns or routing conditions in memory array 102.

In certain aspects, the circuitry 200 tracks global signal loading on global RC tracking path 242. As illustrated, the global RC tracking path 242 is coupled directly into cross-coupled SR latch circuit 202. A feedback net 244 aligned with global RC tracking path 242 explicitly tracks global signal load capacitance present on global signal lines 128. Optionally, in some aspects, an additional return tracking conductor can be connected at net 244 within the feedback path, explicitly enabling resistance (R) tracking similar to dummy-word-line (DWL) tracking techniques. For example, without such an optional conductor, net 244 primarily tracks capacitance (C) loading.

During global signal transitions (SEL_VL 124, nSEL_VL 126), the circuitry 200 ensures precise sequential activation of headers 116, 118 within each power multiplexer (PMUX) 110. For instance, during SEL_VL transitions (e.g., logical “0” to “1”), the circuitry 200 reliably ensures that header transistor 118 (e.g., coupling voltage supply VDDPE 114) is activated slightly before header transistor 116 (e.g., coupling voltage supply VDDCE 112) is disabled, and vice versa. This sequential activation maintains continuous and stable power delivery, inherently preventing simultaneous activation (i.e., allow for non-simultaneous activation) of headers 116, 118 and the associated crowbar currents. The programmable delay elements 206a, 206b explicitly shape and refine overlap durations, ensuring consistent power continuity through header transitions.

Moreover, in certain implementations, the circuitry 200 explicitly addresses an additional scenario involving power-down (PDW/NPDW) transitions. For instance, during the power-down mode, initial circuit conditions include both rails for BSEL_PG 122a and BNSEL_PG 122b having logical “0” states, resulting in both headers 116 and 118 being turned off. At the initiation of transitioning out of power-down mode (e.g., PDW transitioning from “1” to “0”, and NPDW transitioning from “0” to “1”), the feedback provided to the OR gates of the set-reset (SR) latch within the feedback circuit 202 is initialized to a logical “0.” Thus, complementary signals are immediately generated based on the initial logical stage of the global control signal SEL_VL (e.g., independent of RC or C loading). For example, if SEL_VL is initially “1,” then BNSEL_PG 122b transitions to “1”, while BSEL_PG 122a remains at “0”; conversely, if SEL_VL is initially “0”, then BSEL_PG 122a transitions to “1”, while BNSEL_PG 122b remains “0”. Accordingly, the complementary signals generated by the feedback circuit 202, based on these defined initial conditions, reliably prevent simultaneous activation (i.e., reliably allow for non-simultaneous activation) of both header transistors 116 and 118; thereby effectively avoiding significant crowbar currents when transitioning out of power-down mode. Thus, only one header transistor (116 or 118) reliably activates initially, with the complementary header transistor reliably remaining off.

To clarify, advantageously, the circuitry 200 addresses two distinct voltage overlap conditions in a unified circuit solution: 1) first, during normal operational transitions triggered by SEL_VL 124 switching, adaptive circuitry 200 dynamically adjusts timing skews based on tracked RC loading conditions on global lines 128, as described above; and 2) second, during transitions triggered explicitly by power-down (PDW/NPDW) signal changes, adaptive circuitry 200 inherently generates timing offsets based explicitly on initial circuit conditions and feedback configuration states, ensuring headers 116, 118 do not simultaneously activate upon exiting a power-down mode, thereby eliminating significant crowbar currents in this scenario.

Accordingly, FIG. 2 advantageously illustrates circuitry 200 employing cross-coupled feedback circuit 202 with programmable delay elements 206a, 206b and/or capacitance (C) tracking/or optional resistance-capacitance (RC) tracking capabilities via conductor at net 244. Hence, the circuit 200 comprehensively addresses voltage overlap race conditions and spatial voltage skew issues during both normal operational transitions and transitions associated explicitly with exiting power-down modes (e.g., independent of tracking) particularly in integrated memory arrays 102 having numerous column I/O regions.

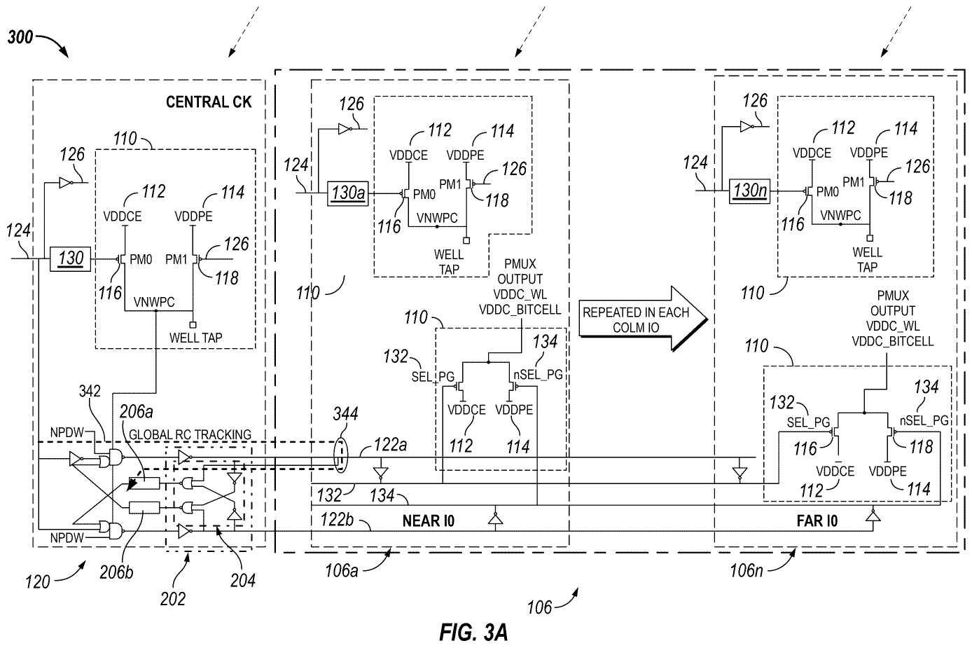

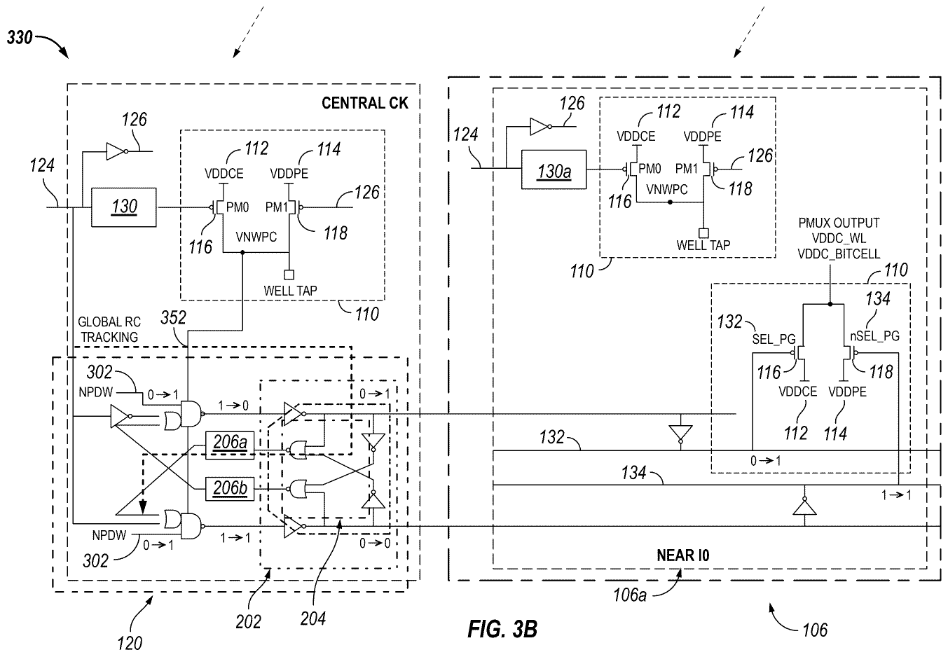

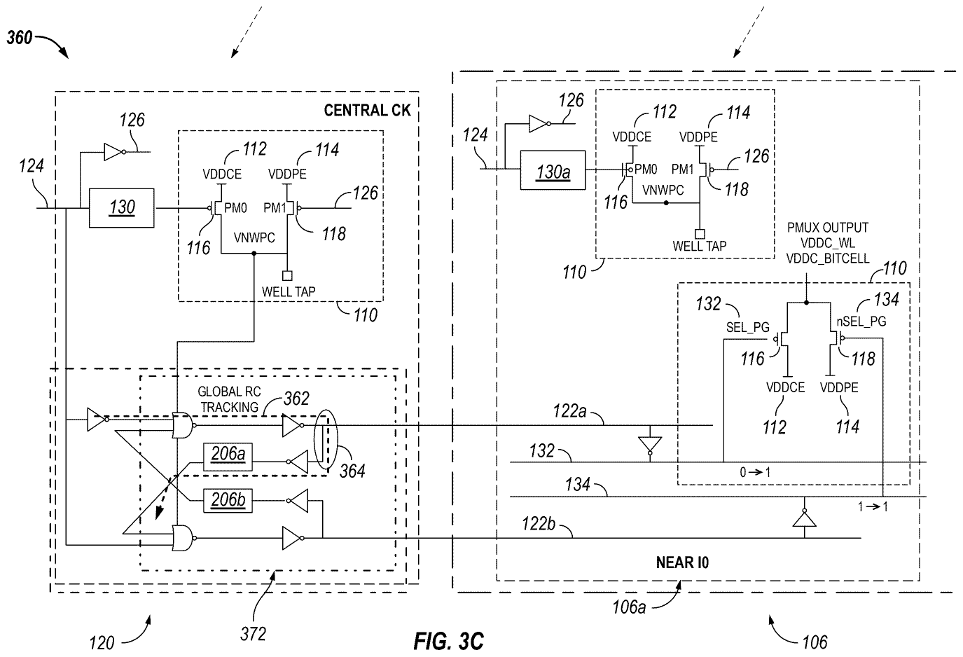

Referring to FIG. 3A, a circuit 300 implementing adaptive feedback-based delay tracking is shown according to example implementations. In certain aspects, circuit 300 (e.g., adaptive feedback-based delay tracking circuitry; adaptive circuitry; adaptive feedback circuitry; adaptive tracking circuitry) provides robust timing overlap margins when managing voltage transitions in an integrated memory array 102 having a large plurality of column input-output (I/O) regions 106a-106n. Similar to implementations described with reference to FIGS. 1 and 2, a central control circuit (Central CK) 120 generates complementary global control signals, SEL_VL 124 and nSEL_VL 126, propagated via global signal lines 128 across multiple I/O regions 106a-106n.

In certain implementations, the feedback circuitry portion 202 employs cross-coupled feedback paths formed by an SR-latch configuration. Specifically, the feedback circuitry portion 202 tracks global loading (e.g., capacitance loading or resistance-capacitance (RC) loading) associated with global signals BSEL_PG and BnSEL_PG, corresponding respectively to local complementary signals SEL_PG 132 and nSEL_PG 134. For example, the circuit 300 adaptively generates a precise timing skew between signals SEL_PG 132 and nSEL_PG 134, which dynamically adjusts based on the tracked global loading conditions. In some aspects, for instance, circuitry portion 202 inherently ensures reliable overlap margins, whereby during a transition of SEL_VL 124 from logical “0” to “1”, header transistor 118 coupling supply VDDPE 114 turns on prior to header transistor 116 coupling supply VDDCE 112 turning off, and vice versa, maintaining continuous and stable power delivery without excessive crowbar current.

As further depicted, the circuit 300 includes programmable delay elements (PROG delays) 206a, 206b integrated within the SR latch feedback paths. These programmable delay elements 206a, 206b are selectively tunable based on specific C or RC loading conditions or operational requirements of the memory array 102, precisely shaping the duration of timing overlap between complementary headers 116 and 118 within each PMUX 110, thereby maintaining consistent power continuity.

In certain implementations, circuitry 300 further includes a global RC tracking path 342 coupled from the Central CK 120 and extending to at least the near I/O region 106a. Specifically, the global C or RC tracking path 342 includes a feedback net 344 configured to dynamically track the global signal line 128 loading. In some cases, the feedback net 344 primarily tracks capacitance (C) loading associated with the global signal lines 128. Additionally, an optional programmable return tracking conductor can be selectively connected at feedback net 344, enhancing tracking precision by incorporating resistance (R) tracking similar to known dummy-word-line (DWL) resistance tracking methods. Thus, the circuitry 300 can be dynamically tuned for precise timing offset control between complementary signals SEL_PG 132 and nSEL_PG 134, effectively adapting to varying conditions and column sizes within memory array 102.

Furthermore, in certain cases, the circuitry 300 illustrated in FIG. 3A represents an additional cross-coupled feedback implementation specifically addressing voltage transition challenges associated with exiting a power-down mode. For example, when transitioning out of a power-down mode, both headers 116, 118 initially remain off. Without such circuitry 300, both headers 116, 118 might momentarily turn on simultaneously, causing substantial crow bar current. Advantageously, due to the presence of the feedback aspects of the circuitry 300, only one header transistor (e.g., either header 116 or 118) reliably turns on initially, while the other remains off, preventing simultaneous activation (i.e., allowing for non-simultaneous activation) and significantly reducing crowbar currents during transitions from power-down modes. Consequently, the feedback circuitry portion 202 within the circuit 300 advantageously provides dual-mode adaptive timing offset control. First, during normal operation, timing offsets are dynamically adapted based on the tracked RC or C loading on global signal lines 128. Second, during transitions out of power-down modes, timing offsets between complementary local signals SEL_PG 132 and nSEL_PG 134 are independently set based on initial circuit conditions and configuration states (e.g., similar to as described in above sections), thus reliably eliminating excessive crowbar current in both operational scenarios.

Referring to FIG. 3B, a circuit 330 implementing adaptive feedback-based delay tracking is shown according to example implementations. In certain aspects, the circuit 330 is configured to mitigate crowbar currents during transitions from a power-down state. For instance, the circuit 330 effectively addresses conditions where simultaneous activation of power multiplexer (PMUX) headers 116, 118 might otherwise occur due to transitions from a power-down condition (e.g., PDW transition from logic high “1”→logic low “0”). As previously discussed, simultaneous activation of PMUX headers 116, 118 can result in substantial crowbar currents, particularly in cases involving significant voltage differential (e.g., first voltage supply VDDPE 114 at 0.50V and second voltage supply VDDCE 112 at 0.75V).

In various cases, the circuit 330 includes feedback circuitry portion 202 that specifically manages transitions related to the inverted power-down control signal NPDW 302 (e.g., generated from PDW transitioning from logic high “1” to logic low “0”). During transitions out of the power-down state (e.g., PDW transitioning from “1” to “0”, corresponding to NPDW transitioning from “0” to “1”), both complementary global control signals SEL_VL 124 and nSEL_VL 126 initially propagate conditions which, without feedback intervention, could lead to simultaneous activation of both PMUX headers 116, 118. As noted, simultaneous activation of PMUX headers 116, 118 could result in excessive crowbar current between voltage supplies VDDCE 112 and VDDPE 114 due to the significant voltage differential.

To address this issue, feedback circuitry portion 202 incorporates a modified cross-coupled latch-based feedback structure 204, configured as a set-reset (SR) latch, specifically responsive to changes in the NPDW signal 302 as well as the SEL_VL and nSEL_VL signals 124, 126. This feedback circuitry portion 202 inherently and rapidly detects any initial simultaneous activation conditions based on internal logic states, and quickly resolves such overlaps by selectively ensuring the activation of only one intended header (e.g., either the header transistor 116 associated with VDDCE 112 or header transistor 118 associated with VDDPE 114), thereby substantially mitigating or eliminating the potential crowbar current.

Furthermore, the feedback circuitry portion 202 includes programmable delay elements (PROG delays) 206a, 206b integrated within the feedback paths of the cross-coupled latch 204. Programmable delay elements 206a, 206b facilitate precise and adjustable timing control, allowing selective tuning of timing offsets specifically during power-down transitions initiated by PDW (or NPDW) signal changes. Thus, the feedback circuitry portion 202 ensures reliable and continuous power delivery to memory bitcells 104 without significant crowbar current, even under substantial voltage differential conditions between voltage supplies 112 and 114.

Additionally, as illustrated by the provided truth table below, the feedback circuitry portion 202 specifically manages header activation based on combinations of NPDW 302, SEL_VL 124, and nSEL_VL 126 signals:

| NPDW | nSEL_VL | SEL_VL | BSEL_PG | BnSEL_PG |
|---|---|---|---|---|
| 0 | 0 | 0 | 0 | 0 |
| 0 | 0 | 1 | 0 | 0 |
| 0 | 1 | 0 | 0 | 0 |
| 0 | 1 | 1 | 0 | 0 |
| 1 | 0 | 0 | NA | NA |
| 1 | 0 | 1 | 0 | 1 |
| 1 | 1 | 0 | 1 | 0 |
| 1 | 1 | 1 | NA | NA |

As may be appreciated, the truth table explicitly demonstrates the internal logic conditions managed by the feedback circuitry portion 202. For example, as the NPDW signal 302 transitions from “0” to “1” (e.g., indicating an exit from power-down), specific internal logic conditions initially present a potential scenario of simultaneous header activation (e.g., BSEL_PG 112a and BnSEL_PG 112b both initially low, potentially turning both headers on). In response, the cross-coupled latch-based feedback circuitry 204 rapidly resolves this potential overlap, ensuring the final state is stable and prevents simultaneous activation (i.e., allows for non-simultaneous activation) of both headers. Consequently, FIG. 3B, advantageously, illustrates an improved adaptive feedback circuit implementation that manages voltage transitions and header activation specifically during power-down transitions by selectively using NPDW 302 input along with SEL_VL 124 and nSEL_VL 126 signals. This configuration significantly reduces crowbar current between power supplies and improves reliability, efficiency, and robustness of integrated memory circuit 100 under power-down-related transitions.

Referring to FIG. 3C, a circuit 360 implementing example adaptive feedback-based delay tracking without power-down signals (e.g., PDW/NPDW) is shown according to example implementations. In certain aspects, the circuit 360 (e.g., adaptive feedback-based delay tracking circuitry; adaptive circuitry; adaptive feedback circuitry; adaptive tracking circuitry) provides robust crowbar current mitigation using solely complementary global control signals SEL_VL 124 and nSEL_VL 126, without reliance on explicit power-down transitions.

In this implementation, the circuitry 360 includes cross-coupled feedback paths arranged in a set-reset (SR) latch 372 configuration. Specifically, the cross-coupled feedback circuitry 372 dynamically manages complementary global signals SEL_VL 124 and nSEL_VL 126 based on their transitions alone, independent from any explicit power-down input signals. Accordingly, the circuit 360 includes global RC tracking path 362 configured to dynamically track global signal line loading (e.g., C or RC loading) and ensure precise timing offsets between the complementary local control signals SEL_PG 132 and nSEL_PG 134. More particularly, the circuitry 360 provides a programmable feedback through net 364. For instance, the net 364 tracks the global signal load capacitance along global RC tracking path 362. Programmable delay elements (“PROG delays”) 206a, 206b are incorporated within the feedback paths, enabling dynamic adjustment of timing offsets. Such programmability allows fine-tuning of the crowbar current duration that may occur transiently during specific SEL_VL 124 and nSEL_VL 126 -switching transitions.

In certain implementations, during a SEL_VL transition (e.g., SEL_VL transitioning from logic high “1” to logic low “0” and correspondingly nSEL_VL from “0” to “1”), the VDDCE headers (e.g., header transistor 116) initially turn ON, while VDDPE headers (e.g., header transistor 118) may remain transiently activated until the cross-coupled feedback circuitry 372 activates. This transitional overlap may briefly cause a small-duration crowbar current, particularly if there exists a substantial voltage differential between the selectable voltage supplies VDDCE 112 and VDDPE 114. Nevertheless, the circuitry 360 quickly resolves this overlap by ensuring timely deactivation of the VDDPE headers, minimizing crowbar current effectively and rapidly. Moreover, in some cases, programmable feedback through net 364 specifically allows adjustment of the delay before feedback activation occurs. Thus, the circuit 360 adaptively controls the transient overlap, limiting crowbar current to negligible durations. Consequently, even during SEL_VL transitions, the circuitry 360 reliably ensures continuous and stable voltage delivery to memory bitcells 104 while minimizing excessive transient currents between power supplies.

In various implementations, the logic states of complementary global control signals SEL_VL 124, nSEL_VL 126, and resulting complementary local control signals BSEL_PG 122a, BnSEL_PG 122b, are illustrated in the below truth table. As shown, the circuitry 360 consistently enforces complementary operation of PMUX headers, thereby inherently preventing simultaneous activation (i.e., allowing for non-simultaneous activation) and crowbar conditions.

| nSEL_VL | SEL_VL | BSEL_PG | BnSEL_PG |
|---|---|---|---|
| 0 | 1 | 0 | 1 |
| 1 | 0 | 1 | 0 |

Advantageously, FIG. 3C illustrates a simplified and efficient circuitry 360 arrangement that eliminates explicit power-down signaling, instead managing voltage transitions and crow bar currents using intrinsic feedback based solely on SEL_VL and nSEL_VL transitions. By employing programmable feedback at net 364, the circuitry 360 achieves precise control of crowbar current durations and robust reliability for integrated memory circuits, particularly under varied operating conditions and voltage differentials between selectable supplies.

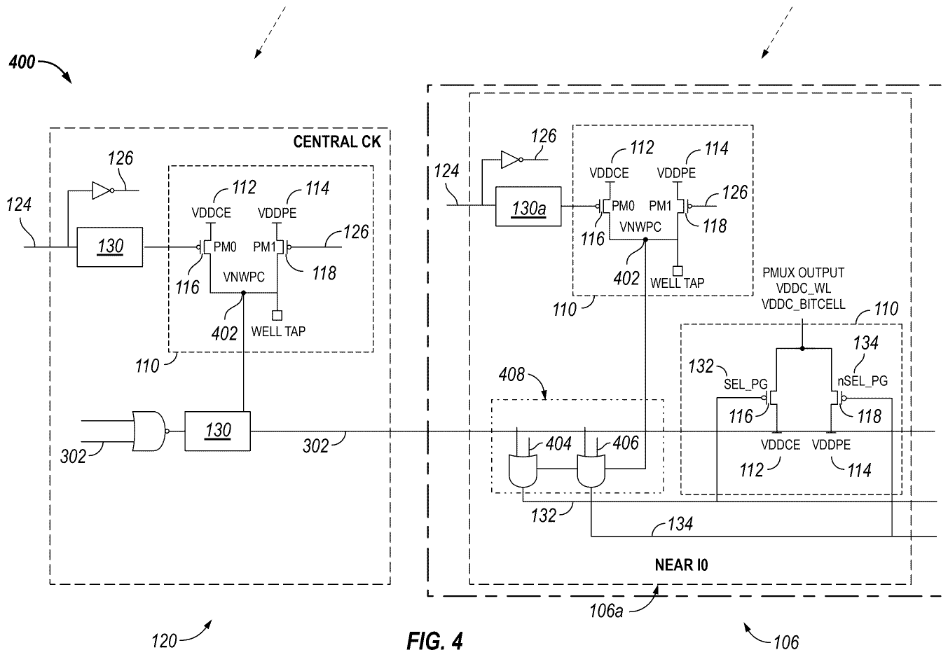

Referring to FIG. 4, a circuit 400 is shown according to example implementations. As illustrated, in certain aspects, the circuit 400 is configured to convert a global timing race condition into a localized timing race within individual input-output (I/O) regions 106. Advantageously, the circuit 400 simplifies the overall circuit design and substantially reduces crowbar currents during voltage supply transitions within integrated memory circuits. In various cases, the circuit 400 includes localized level shifter circuits 130 positioned within each I/O region 106. These level shifter circuits 130 were initially implemented for generating control signals for “always-on” voltage supply headers associated with a stable voltage domain (VNWPC) 402. As explicitly shown in FIG. 4, existing localized level shifter circuits 130 have now been modified to operate from the stable, always-on VNWPC domain 402. This modification enables each localized level shifter circuit 130 to locally generate complementary intermediate signals, specifically iSEL_VL 404 and inSEL_VL 406, directly from a globally propagated signal SEL_VL 124. Thus, by reusing existing level shifters 130 originally intended for VNWPC generation, the circuit 400 converts the previously global timing race condition (associated with core voltage headers) into a localized timing race without impacting controllability of the always-on VNWPC headers 402.

In certain aspects, the complementary intermediate signals iSEL_VL 404 and inSEL_VL 406 operate on the stable VNWPC voltage domain 402 and are inherently complementary by design. This intrinsic complementarity and localized signal generation eliminate the necessity for additional centrally-generated pulse-shaping circuitry previously required in control circuitry. As further shown in FIG. 4, a power-down control signal PDW 302 is centrally generated, level-shifted within the central control circuit 120, and propagated globally to each I/O region 106. Within each I/O region 106, combinational logic gates 408 locally combine (e.g., mix) the level-shifted PDW signal 302 with complementary intermediate signals iSEL_VL 404 and inSEL_VL 406. Correspondingly, the resulting complementary local control signals SEL_PG 132 and nSEL_PG 134 directly control the headers 116, 118 of respective power multiplexers (PMUXes) 110. As discussed, each PMUX header 116, 118 selectively couples respective voltage supplies (e.g., VDDCE 112 and VDDPE 114) to memory bitcells 104.

Advantageously, by converting the global timing race associated with PMUX headers into a localized timing race within each individual I/O region 106, the circuit 400 substantially simplifies the overall design. Specifically, this example implementation significantly reduces complexity of central control circuitry 120 by removing the need for dedicated central pulse-shaping circuits for SEL_VL 124. Moreover, the localized timing management robustly reduces crowbar currents during voltage transitions by ensuring precise local control and stable overlap timing margins at each PMUX header 116, 118. Further, because existing localized level shifter circuitry 130 is reused for the generation of intermediate signals iSEL_VL 404 and inSEL_VL 406, no additional silicon area overhead is incurred. Thus, the circuit 400 significantly enhances overall efficiency, reduces crowbar currents during power supply transitions, and improves the robustness of the integrated memory circuit 100.

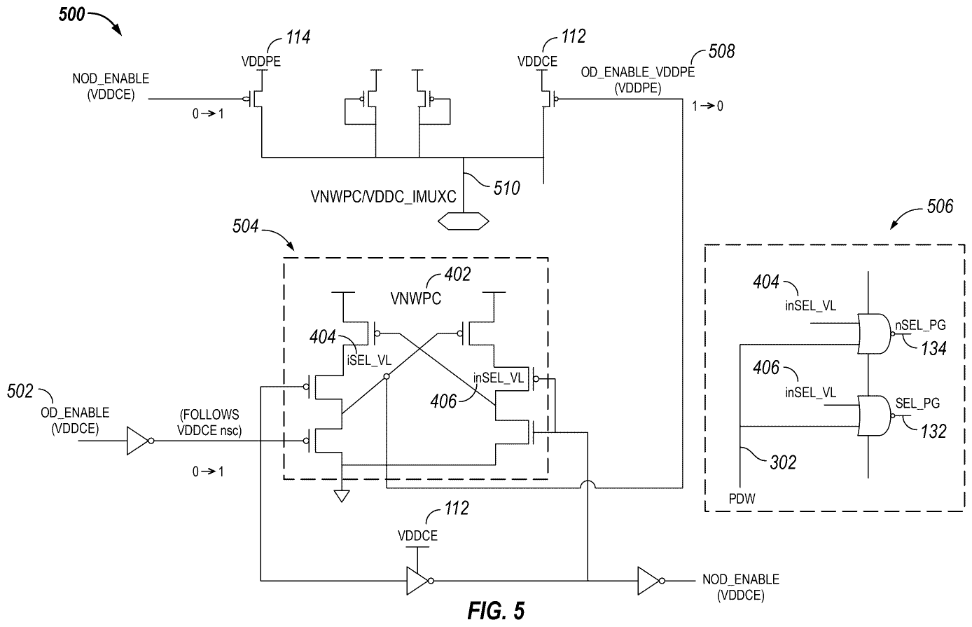

Referring to FIG. 5, a circuit 500 is shown according to example implementations. In certain aspects, the circuit 500 illustrates a localized power multiplexer (PMUX) implementation designed for efficient management of memory array voltage transitions by converting global timing race conditions into localized timing control. As depicted, the circuit 500 includes two distinct sets of headers (e.g., PMUX headers 110). A first set of headers includes transistors configured to selectively couple either a first voltage supply, for example, VDDPE 114, or a second voltage supply, for example, VDDCE 112, to memory bitcells 104 within the memory array. A second set of headers is configured to generate a stable intermediate voltage supply VNWPC 402, which remains constantly enabled (“always ON”).

As specifically shown in FIG. 5, a globally propagated control signal SEL_VL, represented herein as OD_ENABLE 502, is provided to localized level shifter circuitry 130 positioned within individual input-output (I/O) regions. Specifically, the localized level shifter circuitry 130 is powered by the stable intermediate voltage domain VNWPC 402 and generates complementary intermediate signals, specifically iSEL_VL 404 and inSEL_VL 406, directly from the globally propagated SEL_VL signal 124. In various implementations, intermediate signals iSEL_VL 404 and inSEL_VL 406 inherently possess built-in timing offsets determined by transistor-level configurations within the localized level shifter circuit 130. These built-in timing offsets advantageously enable precise localized control of timing overlaps during voltage transitions.

In the implementation shown, a globally propagated input signal SEL_VL, represented as OD_ENABLE 502, is provided to a localized level shifter circuit 504 positioned within the input-output (I/O) regions. Specifically, the localized level shifter circuit 504, powered by the stable intermediate voltage domain VNWPC 402, generates complementary intermediate signals, specifically iSEL_VL 404 and inSEL_VL 406, directly from the globally propagated SEL_VL (OD_ENABLE) signal 502. In various implementations, the intermediate signals iSEL_VL 404 and inSEL_VL 406 inherently possess built-in timing offsets determined by transistor-level configurations within the localized level shifter circuit 504. These built-in timing offsets advantageously enable precise localized control of timing overlaps during voltage transitions.

Additionally, the circuit 500 further includes combinational logic 506 positioned within each localized I/O region. As explicitly depicted, the combinational logic 506 locally combines (e.g., logically mixes) intermediate signals iSEL_VL 404 and inSEL_VL 406 with a globally propagated power-down control signal PDW 302. As a result, the combinational logic 506 generates final complementary local control signals, specifically SEL_PG 132 and nSEL_PG 134. These complementary local control signals SEL_PG 132 and nSEL_PG 134 directly control timing overlap between enabling and disabling respective PMUX headers 110, selectively coupling voltage supplies VDDPE 114 and VDDCE 112 to the memory bitcells.

Furthermore, as illustrated, the PMUX headers 110 provide an output at node OD_ENABLE_VDDPE 508, explicitly indicating header activation states. Moreover, node VNWPC/VDDC_IMUXC 510 serves as a common output node coupling headers associated with the always-on intermediate V NW PC supply 402 and the second voltage supply VDDCE 112. The precise coordination of these nodes (508, 510) through locally generated complementary signals (SEL_PG 132, nSEL_PG 134) substantially reduces crowbar currents during voltage transitions, improving the overall operational robustness and efficiency of circuit 500.

In certain aspects, the circuit 500 advantageously shifts global timing race management from a centrally controlled propagation scheme to a localized timing management approach. Each localized level shifter circuit 504 inherently resolves timing races locally, thus eliminating the need for additional dedicated pulse-shaping circuitry previously required in central control circuitry. Consequently, localized generation of complementary signals SEL_PG 132 and nSEL_PG 134 achieves significant reductions in spatial voltage skew, crowbar currents, and central circuit complexity. Additionally, this localized management strategy incurs minimal additional circuit area overhead, enhancing the overall robustness, efficiency, and reliability of integrated memory arrays. Accordingly, FIG. 5 demonstrates an advanced, localized circuit topology within the integrated memory circuit. Advantageously, the circuit 500 inherently resolves previously challenging timing race conditions locally, significantly simplifies the central control circuitry, eliminates excessive crowbar currents between power domains, and substantially improves overall power delivery reliability and efficiency within integrated memory arrays.

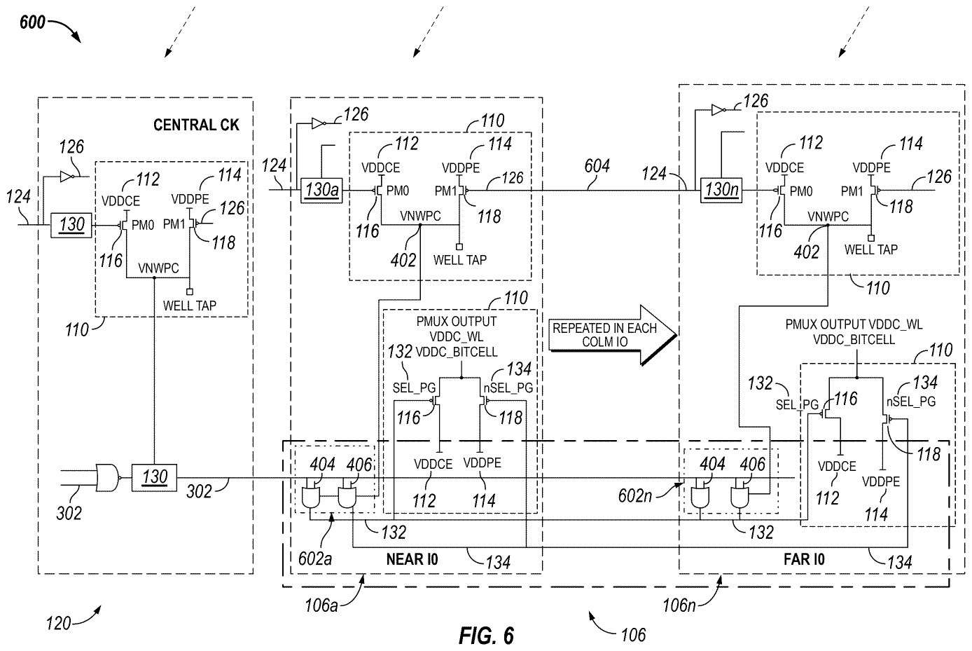

Referring to FIG. 6, a circuit 600 is shown according to example implementations. In certain aspects, the circuit 600 is an improved integrated memory circuit configured to mitigate spatial voltage skew caused by resistance-capacitance (RC) delays during propagation of global control signals, such as SEL_VL 124, across multiple column input-output (I/O) regions 106a-106n within a memory array.

Specifically, in various cases, the global signal SEL_VL 124 is routed on a low-resistance conductor track 604 that significantly reduces intrinsic RC propagation delays. Despite this optimized routing, residual RC delays remain between a near I/O region 106a and a far I/O region 106n. To address this, the circuit 600 includes localized driver circuits 602a, 602n (e.g., programmable driver circuits 140 in FIG. 1) periodically positioned along global signal lines (e.g., global signal line 128), such as at selected intervals (e.g., every fourth column I/O region). These localized driver circuits 602a, 602n actively reinforce the propagation of control signals SEL_PG 132 and nSEL_PG 134 routed globally along low-resistance conductor track 604, thus minimizing spatial voltage skew by controlling PM OS gate signals of PMUX headers 116, 118 in a cooperative manner.

In an example operation, during signal transitions, localized driver circuits 602a located closer to the central control circuit (Central CK) 120 attempt to initiate an early transition of the SEL_PG signal 132. However, localized driver circuits 602n located in far I/O regions temporarily counteract this early transition due to inherent propagation delay along track 604. Thus, the SEL_PG signal 132 fully transitions only after all localized driver circuits 602a, 602n, including those in far column regions, are activated. Advantageously, this cooperation among the distributed local drivers 602a, 602n results in substantially simultaneous activation of PMUX headers 116, 118 across the memory array, significantly mitigating spatial voltage skew.

Furthermore, selective activation and periodic positioning of localized driver circuits 602a, 602n help avoid sharp signal transitions along global signal lines, reducing transient effects and peak power consumption. Due to the infrequent toggling of SEL_PG and nSEL_PG signals, momentary short-circuit currents between localized driver circuits 602a, 602n have negligible impact on overall circuit performance or reliability. Consequently, the improved localized driver circuit implementation depicted in FIG. 6 effectively reduces spatial voltage skew and peak current draw during transitions. By enabling uniform activation of PMUX headers 116, 118 throughout memory arrays with minimal overhead or complexity, the integrated circuit 600 enhances reliability and operational robustness in various memory circuit implementations.

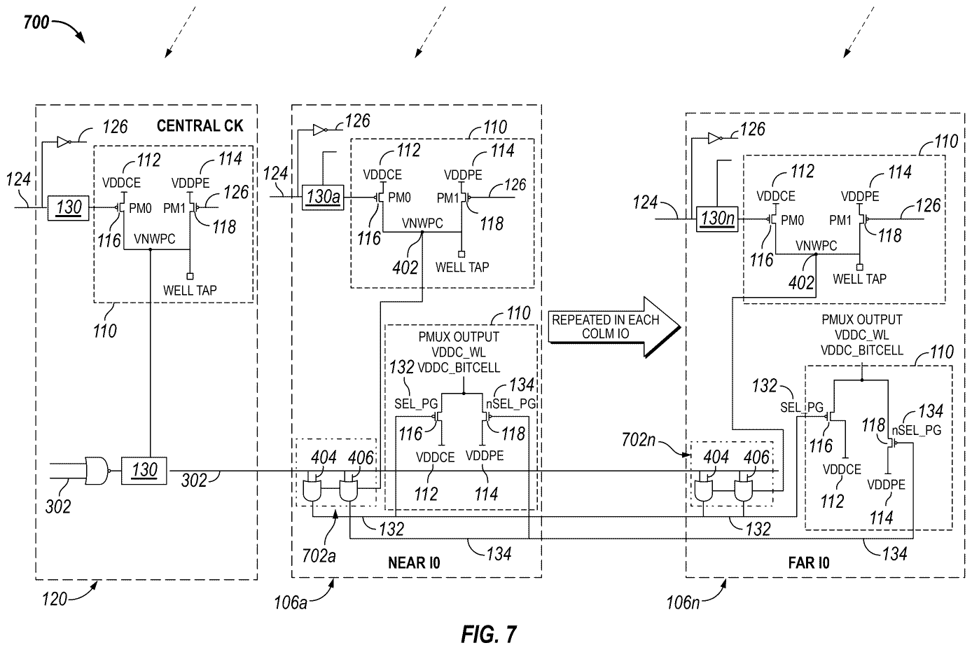

Referring to FIG. 7, a circuit 700 is shown according to example implementations. In certain aspects, the circuit 700 efficiently manages timing race conditions associated with power multiplexer (PMUX) header activation across multiple column input-output (I/O) regions 106a-106n within a memory array. The circuit 700 advantageously relocates combinational logic into each individual I/O region 106, simplifying central control circuitry 120 and substantially reducing spatial voltage skew and crowbar current during voltage supply transitions.

As illustrated, in certain aspects, the central control circuit (“Central CK”) 120 generates a global control signal SEL_VL 124. This global signal SEL_VL 124 propagates via a low-resistance global signal line across the plurality of I/O regions 106a-106n (e.g., near I/O 106a, far I/O 106n). Each I/O region 106 includes localized level shifter circuitry 130, which is now powered from a stable, always-on intermediate voltage domain VNWPC 402. By leveraging existing localized level shifter circuits 130 within each I/O region 106, complementary intermediate signals iSEL_VL 404 and inSEL_VL 406 are locally generated from the globally routed SEL_VL signal 124.

Additionally, a power-down signal PDW 302 is centrally generated at the central control circuit 120, level-shifted centrally via level shifter circuitry, and then propagated globally across each I/O region 106. Within each I/O region 106, combinational logic gates 702 (e.g., 702a, . . . 702n) locally combine (mix) the globally routed PDW signal 302 with intermediate complementary signals iSEL_VL 404 and inSEL_VL 406. This local combination produces complementary local control signals SEL_PG 132 and nSEL_PG 134, directly controlling PMUX headers 116, 118 configured to selectively couple respective voltage supplies, such as VDDCE 112 and VDDPE 114, to memory bitcells 104.

By strategically reusing localized level shifter circuitry 130 for generating complementary intermediate signals 404, 406, the circuit 700 advantageously eliminates the need for dedicated central combinational logic previously required to manage global timing race conditions. This localized generation and mixing substantially simplify overall central control circuit 120 complexity, converting global timing race conditions into easily manageable localized timing races. Moreover, localized generation of complementary local control signals SEL_PG 132 and nSEL_PG 134 significantly reduces spatial voltage skew across the I/O regions 106a-106n and prevents excessive crowbar currents during transitions. Thus, the circuit 700 provides improved performance and reliability without incurring additional silicon area overhead or significant complexity. Accordingly, the improved circuit topology depicted in FIG. 7 efficiently converts global timing race management into localized timing control, thereby significantly enhancing reliability and performance within integrated memory arrays having numerous column I/O regions.

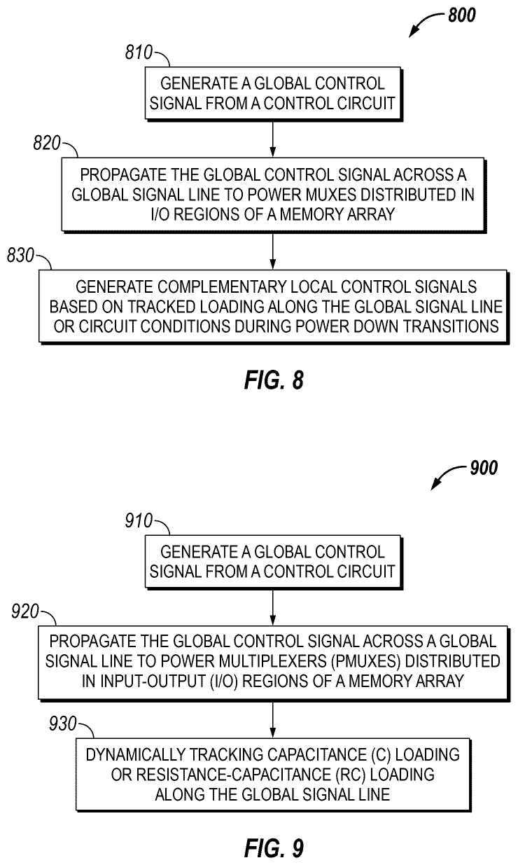

Referring to FIG. 8, a method 800 of managing voltage transitions in an integrated memory circuit is shown according to example implementations. In various cases, the method 800 provides efficient management of voltage transitions and substantially reduces spatial voltage skew and crowbar currents within memory arrays with multiple input-output (I/O) regions. In certain aspects, the method 800 leverages adaptive circuitry (e.g., adaptive feedback and/or tracking circuitry 200, 300, 360, as previously illustrated in FIGS. 1, 2, and 3A-3C), configured to dynamically adjust complementary local control signals based on real-time loading conditions along global signal lines, or initial circuit conditions during transitions from power-down modes.

At block 810, the method 800 includes generating a global control signal from a control circuit (e.g., central control circuit 120, as depicted previously in FIGS. 1 and 2). For example, the global control signal may include complementary global signals such as SEL_VL and nSEL_VL, as previously described herein.

At block 820, the method includes propagating the global control signal generated at block 810 across a global signal line (e.g., global signal line 128) to power multiplexers (PMUXes) distributed within multiple I/O regions of the memory array (e.g., PMUXes 110 distributed within I/O regions 106a-106n). As previously detailed, the global signal line 128 includes a low-resistance conductive track designed to minimize intrinsic resistance-capacitance (RC) delays and associated spatial skew.

At block 830, the method further includes generating complementary local control signals (e.g., SEL_PG and nSEL_PG) based on tracked loading conditions along the global signal line or based on initial circuit conditions during transitions out of a power-down mode. For instance, adaptive circuitry (e.g., as illustrated previously in FIGS. 1-3C) adaptively generates local control signals having dynamically adjusted timing offsets.

In certain implementations, the tracked loading conditions include real-time measurement of RC or capacitance (C) loading along the global signal line. This adaptive tracking enables complementary local control signals to have timing skews dynamically adjusted, thereby ensuring at least one of:
(a) substantially simultaneous activation of the PMUXes across the plurality of I/O regions, thereby significantly minimizing spatial voltage skew within the memory array; or
(b) a controlled timing overlap between enabling of one PMUX header and disabling of another complementary PMUX header within each PMUX, thus effectively avoiding or substantially reducing crowbar currents during voltage transitions.

Additionally, in certain scenarios, complementary local control signals are generated independently of tracked RC or C loading conditions. Specifically, during transitions out of a power-down mode (e.g., PDW transitioning from “1” to “0,” and NPDW transitioning from “0” to “1”), initial circuit conditions (such as initial logical states of global control signals SEL_VL, BSEL_PG, BNSEL_PG) determine complementary local signal generation. Under these initial conditions, the cross-coupled adaptive feedback circuitry reliably generates complementary signals to prevent simultaneous activation (i.e., allow for non-simultaneous activation) of PMUX headers, thereby effectively preventing crowbar currents at transitions from power-down modes.

In some implementations, the method further includes selectively activating programmable local driver circuits positioned periodically along the global signal line (e.g., local driver circuits 140, 602a, 602n, selectively positioned as described previously in FIG. 1 and FIG. 6). Selective activation of these local drivers dynamically reduces propagation delay variations, further enhancing uniform signal propagation and stable activation of PMUX headers across I/O regions.

In alternative implementations, generating complementary local control signals includes localized level shifting of the globally propagated control signal within each respective I/O region. For example, existing localized level shifter circuits (such as localized level shifter circuits 130, depicted in FIGS. 4, 5, and 7), powered from a stable intermediate voltage domain (e.g., VNWPC 402), inherently generate intermediate local complementary signals (iSEL_VL 404, inSEL_VL 406), providing intrinsic timing offsets. These locally generated intermediate signals significantly simplify central control circuitry requirements and enhance local timing control robustness.

Furthermore, in some aspects, adaptively generating complementary local control signals includes using programmable delay elements within cross-coupled feedback circuitry (e.g., PROG delays 206a, 206b, as shown previously in FIGS. 2, 3A). These programmable delay elements provide selective and precise tuning of timing offsets in response to measured C or RC loading conditions, optimizing overlap durations and ensuring continuous, reliable power delivery during transitions.

Accordingly, the method 800 depicted in FIG. 8 provides a robust, adaptive solution for efficiently managing voltage transitions within integrated memory arrays. Advantageously, the method 800 dynamically adapts signal timing based on real-time tracked loading conditions or explicitly defined initial circuit conditions, thereby significantly reducing spatial voltage skew, avoiding crowbar currents, and ensuring reliable, efficient, and robust operation across memory arrays comprising multiple I/O regions.

Referring to FIG. 9, a method 900 of managing voltage transitions in an integrated memory circuit is shown according to example implementations. In certain aspects, the method 800 efficiently manages timing race conditions and minimizes spatial voltage skew within memory arrays comprising a plurality of input-output (I/O) regions. In various implementations, method 800 employs adaptive feedback tracking circuitry (e.g., adaptive tracking circuitry, adaptive feedback circuitry illustrated previously in FIGS. 2, 3A-3C) configured to dynamically track capacitance (C) loading or resistance-capacitance (RC) loading along global signal lines, enabling dynamic adjustment of timing skews between complementary local control signals based on real-time loading conditions.

At block 910, the method 900 includes generating a global control signal from a control circuit (e.g., central control circuit 120, as depicted previously in FIGS. 1 and 2). For instance, the generated global control signal may comprise complementary global signals (e.g., SEL_VL, nSEL_VL) used to control voltage transitions within the memory circuit.

At block 920, the global control signal generated at block 910 is propagated across a global signal line (e.g., global signal line 128) to power multiplexers (PMUXes) distributed within multiple I/O regions of the memory array (e.g., PMUXes 110 distributed within I/O regions 106a-106n). For example, the global signal line is configured as a low-resistance conductor track to minimize intrinsic resistance-capacitance (RC) delays.

At block 930, the method further includes dynamically tracking capacitance (C) loading or resistance-capacitance (RC) loading along the global signal line. For example, tracking circuitry (such as adaptive feedback circuitry 202 depicted in FIGS. 1, 2 and 3A) is configured to actively monitor RC or C loading conditions. Such dynamic tracking enables real-time assessment of signal propagation characteristics across the global signal line.

In certain implementations, the method 900 further includes adaptively generating complementary local control signals (e.g., SEL_PG and nSEL_PG) at each respective I/O region. The complementary local control signals have timing skews dynamically adjusted based on the tracked C or RC loading conditions. As shown, for example, in FIGS. 1, 2, 3A-3C, cross-coupled feedback circuitry comprising set-reset (SR) latch structures is implemented within adaptive feedback circuitry, dynamically adapting timing skews in response to the tracked loading.

In various aspects, the complementary local control signals are utilized to control PMUX headers (e.g., headers 116, 118) in each respective PMUX. The timing offsets provided by these adaptively generated complementary local control signals ensure at least one of:
(a) substantially simultaneous activation of the PMUXes across the plurality of I/O regions, thereby significantly minimizing spatial voltage skew within the memory array; or
(b) a controlled timing overlap between enabling of one PMUX header and disabling of another complementary PMUX header within each PMUX, thus effectively avoiding or substantially reducing crowbar currents during voltage transitions.

Additionally, in some cases, the method includes selectively activating local driver circuits positioned periodically along the global signal line (e.g., local driver circuits 140 selectively positioned in FIG. 1 and FIG. 6). For instance, the selective activation of these local drivers dynamically reduces propagation delay variations along the global signal line, contributing further to uniform signal propagation and stable activation of PMUX headers.

In an alternative implementation, an example method for managing voltage transitions can include the following steps: generating a global control signal from a control circuit; propagating the global control signal across a global signal line to power muxes distributed in I/O regions of a memory array; and generating complementary local control signals based on tracked loading along the global signal line or circuit conditions/configurations during power down transitions.

Furthermore, in certain aspects, adaptively adjusting timing skews is performed using programmable delay elements incorporated within cross-coupled feedback circuitry. For instance, the programmable delay elements, as illustrated previously (e.g., PROG delays 206a, 206b in FIGS. 2, 3A), enable precise and selective tuning of timing offsets in response to dynamically measured C or RC loading conditions, providing further optimization of timing overlaps and power continuity.

Moreover, in some cases, generating complementary local control signals includes localized level shifting of the globally propagated control signal within each respective I/O region. For example, as depicted in FIGS. 4, 5, and 7, existing localized level shifter circuits 130 powered from a stable intermediate voltage domain (VNWPC 402) inherently provide intrinsic timing offsets and local complementary signals (ISEL_VL 404, inSEL_VL 406), significantly simplifying the central control circuitry and ensuring robust local timing control.

Accordingly, the method 900 depicted in FIG. 9 provides a comprehensive solution for adaptively managing voltage transitions, dynamically controlling timing skews, minimizing spatial voltage skew, and effectively avoiding crowbar currents across integrated memory circuits, especially those comprising large arrays of memory bitcells distributed across numerous I/O regions.

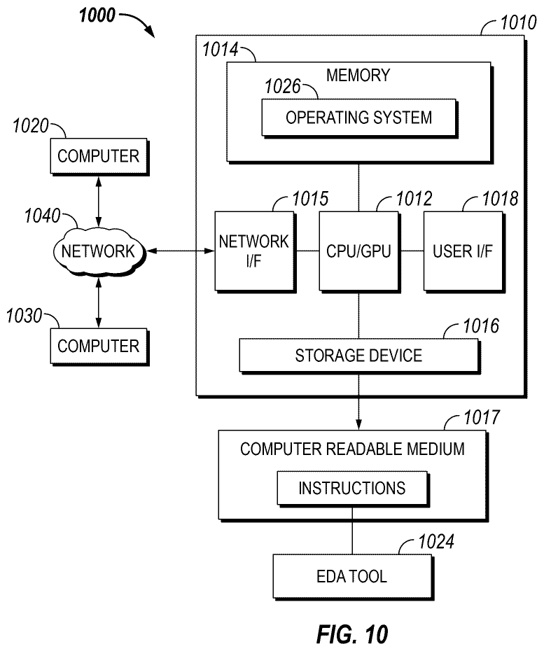

FIG. 10 illustrates example hardware components in a computer system 1000 that may be utilized to facilitate the design, verification, simulation, and optimization of the inventive integrated memory circuit 100 and associated adaptive circuitry described herein. In certain implementations, the computer system 1000, which may represent a networked computing environment or server system, includes at least one electronic design automation (EDA) tool 1024 configured to execute software procedures described herein with reference to FIGS. 1-8. For instance, the EDA tool 1024 automates the design, analysis, and implementation of adaptive power multiplexing and feedback-based delay tracking circuits such as those previously described with reference to circuits 100, 200, 300, 330, 360, 400, 500, 600, 700 and methods described by flowchart 800 (FIG. 8) and flowchart 900 (FIG. 9).

In various implementations, the EDA tool 1024 may be included as a component of existing electronic design compiler software. The EDA tool 1024 specifically automates the synthesis, simulation, and verification of circuits described herein, including adaptive tracking and feedback circuitry configured to dynamically track resistance-capacitance (RC) or capacitance (C) loading and adaptively control timing offsets between complementary local control signals (e.g., SEL_PG, nSEL_PG). For example, the EDA tool 1024 may generate and verify transistor-level netlists or custom circuit implementations of adaptive feedback circuitry, including cross-coupled SR latch structures (e.g., feedback circuitry 202, 372 in FIGS. 2, 3A-3C), localized level shifter circuits (e.g., 130, FIGS. 1, 2, 3A-3C, 4, and 5), programmable delay elements (e.g., 206a, 206b, FIG. 2), local driver circuits (e.g., 602a, 602n, FIG. 6), and combinational logic gates (e.g., 408, 702, FIGS. 4 and 7). Functional and transient simulations performed by the EDA tool 1024 validate timing offsets, overlap margins, and spatial voltage skew reductions, confirming robust synchronization and reliable operation across distributed memory arrays.

Additionally, the EDA tool 1024 performs critical timing analyses and dynamic switching evaluations to optimize transistor sizes, header transistor placement (e.g., PMUX headers 116, 118), and associated control logic (such as level shifters 130, combinational logic gates 408), thereby ensuring robust voltage transitions and crow bar current minimization. Physical design steps performed by EDA tool 1024 optimize transistor placement and routing to reduce area, leakage, and C or RC loading on global signal lines (e.g., global lines 128, FIG. 1), enhancing overall circuit performance. Further, the EDA tool 1024 performs formal verification and generates test vectors to ensure correctness, reliability, and manufacturability in silicon implementations.

In certain aspects, procedures described herein (e.g., method 800 of FIG. 8, method 900 of FIG. 9) may be stored as program instructions 1017 in a computer-readable medium, such as storage device 1016 or memory 1014. These instructions 1017 may be executed by one or more computing devices or servers 1010, 1020, 1030. Each computing device 1010, 1020, 1030 may comprise any type of computer, workstation, server, or programmable electronic device. Further, each computing system 1010, 1020, 1030 may operate individually or within a distributed computing system connected via a network 1040. The computer 1010 generally includes a central processing unit (CPU) 1012 (or, alternatively, graphics processing unit (GPU), neural processing unit (NPU), or other specialized processors) having at least one hardware-based processor coupled to memory 1014. The memory 1014 may represent random access memory (RAM), cache memory, non-volatile memory (e.g., flash memory), read-only memory (ROM), or combinations thereof. Additional memory or storage may also be present elsewhere within the computer system 1000, such as supplemental cache memory within the CPU 1012 or virtual memory stored on the storage device 1016 or other computing devices connected via network 1040.

The computer 1010 may further include a user interface (I/F) 1018, allowing interaction with circuit designers or other operators. The interface 1018 typically includes input devices such as keyboards, mice, touchpads, microphones, and output devices such as display monitors or LCD/LED screens. The computer 1010 also includes the network interface (I/F) 1015 coupled to one or more networks 1040 (wired or wireless), enabling communication and data exchange with remote computing devices or servers 1020, 1030. The computer 1010 operates under the control of operating system 1026, which may be stored in the memory 1014 or on the storage device 1016. Example operating systems include UNIX®, Linux®, Windows®, and others known to those skilled in the art. Software components, such as EDA tool 1024 and instructions 1017 for the inventive adaptive power multiplexing and feedback-based delay tracking methods, may execute on CPU 1012 or on multiple CPUs across networked computing devices 1020, 1030.

Databases of computer system 1000 may include cell libraries, technology files, design format files, Open Artwork System Interchange Standard (OASIS/OASIS.MASK) files, EDIF files, and other standard formats stored in memory 1014, storage device 1016, or across networked computers 1020, 1030. The system 1000 supports semiconductor integrated circuit (IC) designs comprising standard cells, intellectual property (IP) blocks, transistor-level custom designs, or combinations thereof. The EDA tool 1024 leverages these database resources and standardized formats to generate optimized transistor-level netlists and layouts that incorporate the inventive adaptive feedback tracking, localized level shifting, local driver implementations, and cross-coupled latch-based control circuits, thereby ensuring improved memory performance, reduced crowbar currents, minimized spatial voltage skew, and enhanced robustness in silicon implementations.

Concepts described herein may be embodied in computer-readable code for fabrication of apparatus embodying the disclosed concepts. The computer-readable code can be used at one or more stages of a semiconductor design and fabrication process, including electronic design automation (EDA), to fabricate integrated circuits implementing the inventive adaptive feedback circuits. The computer-readable code may define hardware description language (HDL) representations (e.g., Verilog, SystemVerilog, Chisel, VHDL, FIRRTL, SystemC) or low-level descriptions (e.g., netlists, layouts, Graphics Database System II (GDSII)). Logic synthesis processes can also generate bitstreams loaded into field-programmable gate arrays (FPGAs) for pre-fabrication testing and verification.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein includes an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which includes one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit for managing voltage transitions comprising:
a memory array comprising a plurality of memory bitcells;
a plurality of input-output (I/O) regions comprising a plurality of power multiplexers (PMUXes), each PMUX comprising a first header and a second header configured to selectively couple a first voltage supply or a second voltage supply to respective memory bitcells within the memory array;
control circuitry coupled to a global signal line and configured to generate a global control signal, wherein the global signal line is configured to propagate the global control signal to each of the plurality of PMUXes; and
adaptive circuitry coupled to the global signal line, wherein the adaptive circuitry is configured to generate complementary local control signals.

2. The circuit of claim 1, wherein the adaptive circuitry is configured to generate complementary local control signals by at least one of:
tracking either capacitance (C) loading or resistance-capacitance (RC) loading along the global signal line and adaptively generating the complementary local control signals based on the tracked C or RC loading; and
generating the complementary local control signals based on one or more circuit conditions during transitions from a power-down mode independent of the tracked C or RC loading.

3. The circuit of claim 1, wherein the generation of the complementary local control signals comprise dynamically adjusting a timing offset between the complementary local control signals based on the tracked C or RC loading, wherein the complementary local control signals provide at least one of:
(a) substantially simultaneous activation of the plurality of PMUXes across the plurality of I/O regions; and
(b) controlled timing overlap between enabling one of the first and the second headers and disabling of the other header within each PMUX.

4. The circuit of claim 1, wherein the adaptive circuitry comprises adaptive tracking and feedback circuitry having cross-coupled feedback paths.

5. The circuit of claim 4, wherein the cross-coupled feedback paths comprise a set-reset (SR) latch, wherein:
the SR latch is configured to activate the first header and the second header non-simultaneously within each PMUX.

6. The circuit of claim 1, further comprising programmable delay elements within the adaptive circuitry, wherein:
the programmable delay elements are selectively tunable based on measured C or RC loading conditions on the global signal line.

7. The circuit of claim 1, further comprising:
local drivers coupled positioned periodically along the global signal line, wherein:
the local drivers are programmable and selectively activated to reduce propagation delay variations across the global signal line.

8. The circuit of claim 1, further comprising:
localized level shifter circuits positioned within each I/O region, wherein:
the localized level shifter circuits are configured to convert the complementary global control signals into complementary local control signals having intrinsic timing offsets.

9. The circuit of claim 8, wherein each localized level shifter circuit is powered from a stable intermediate voltage domain equal to or greater than the voltage levels of the first and second voltage supplies.

10. A circuit for managing voltage transitions comprising:
a memory array comprising a plurality of memory bitcells;
a plurality of input-output (I/O) regions comprising power multiplexers (PMUXes), each PMUX comprising a first header and a second header configured to selectively couple a first voltage supply or a second voltage supply to respective memory bitcells within the memory array; and
a plurality of localized level shifter circuits, each localized level shifter circuit positioned proximate to a respective PMUX within each I/O region and configured to convert a globally propagated control signal into complementary local control signals, wherein:
each localized level shifter circuit is configured to provide timing offsets between the complementary local control signals.

11. The circuit of claim 10, wherein the complementary local control signals control timing overlap between enabling of one header and disabling of the other header in each respective PMUX.

12. The circuit of claim 10, wherein each localized level shifter circuit is powered by a voltage domain having a voltage level equal to or greater than a voltage level of the first voltage supply and the second voltage supply.

13. The circuit of claim 10, further comprising:
combinational logic positioned within each I/O region, wherein:
the combinational logic is configured to combine a globally propagated power-down control signal with intermediate complementary signals generated by the localized level shifter circuits.

14. The circuit of claim 13, wherein the combinational logic outputs the complementary local control signals to provide non-simultaneous activation of the first header transistor and the second header transistor during power-down transitions.

15. The circuit of claim 13, wherein the globally propagated power-down control signal disables both the first header and the second header during power-down transitions irrespective of states of the complementary local control signals.

16. A method of managing voltage transitions comprising:
generating a global control signal from a control circuit;
propagating the global control signal across a global signal line to power multiplexers (PMUXes) distributed in input-output (I/O) regions of a memory array; and
tracking capacitance (C) or resistance-capacitance (RC) loading along the global signal line using adaptive circuitry.

17. The method of claim 16, further comprising:
generating complementary local control signals having timing offsets dynamically adjusted based on the tracked C or RC loading; and
controlling PMUX headers within each I/O region using the complementary local control signals, wherein controlling comprises at least one of:
(a) substantially simultaneous activation of the PMUXes across the I/O regions; and
(b) controlled timing overlap between enabling of one PMUX header and disabling of another PMUX header.

18. The method of claim 16, further comprising:
selectively activating local drivers positioned periodically along the global signal line to reduce propagation delay variations and voltage skew.

19. The method of claim 16, wherein adaptively generating complementary local control signals comprises using cross-coupled feedback circuitry, and further comprising:
adjusting timing offsets by selectively programming delay elements within the cross-coupled feedback circuitry.

20. The method of claim 16, further comprising:
generating complementary local control signals by performing localized level shifting of the global control signal within each I/O region.
